(19) United States
(12) Patent Application Publication
(10) Pub. No.: US 2024/0393834 A1
(43) Pub. Date: Nov. 28, 2024

(54) WINDOW AND DISPLAY DEVICE INCLUDING THE SAME

(71) Applicant: SAMSUNG DISPLAY CO., LTD., YONGIN-SI (KR)

(72) Inventor: SEONGSIK CHOI, Yongin-si (KR)

(21) Appl. No.: 18/630,029

(22) Filed: Apr. 9, 2024

(30) Foreign Application Priority Data
May 25, 2023 (KR) 10-2023-0067837

(51) Int. Cl. G06F 1/16; H10K 59/38; H10K 59/80

(52) U.S. Cl. CPC G06F 1/1637; H10K 59/38; H10K 59/873; H10K 59/8792

(57) ABSTRACT

A window includes a base layer. A first layer is disposed on the base layer. A second layer is disposed on the first layer. A third layer is disposed on the second layer. The second layer includes silicon dioxide (SiO₂) and aluminum oxide (Al₂O₃). A weight ratio of the silicon dioxide to the aluminum oxide in the second layer is in a range of about 25:75 to about 35:65.

### CROSS-REFERENCE TO RELATED APPLICATION

This application claims priority under 35 U.S.C. § 119 to Korean Patent Application No. 10-2023-0067837, filed on May 25, 2023 in the Korean Intellectual Property Office, the disclosure of which is incorporated by reference in its entirety herein.

### 1. TECHNICAL FIELD

The present disclosure herein relates to a window and a display device including the same, and more specifically, to a window having increased mechanical properties as well as a low reflectance, and a display device including the same.

### 2. DISCUSSION OF RELATED ART

Display devices are used in an increasing variety of multimedia devices, such as televisions, mobile phones, tablet computers, and game consoles to provide image information to a user. Recently, various flexible display devices which are foldable or bendable have been developed to provide increased user convenience and portability. Flexible display devices may be deformable in various ways, such as folded, rolled, or bent.

The flexible display device may include a display panel and a window which are foldable or bendable. However, the window of the flexible display device that is deformed by the folding or bending operations may be easily damaged by an external impact.

### SUMMARY

The present disclosure provides a window having a low reflectance and increased mechanical strength.

The present disclosure provides a display device having increased display efficiency and maintaining low reflectance.

According to an embodiment of the present disclosure, a window includes a base layer. A first layer is disposed on the base layer. A second layer is disposed on the first layer. A third layer is disposed on the second layer. The second layer includes silicon dioxide (SiO2) and aluminum oxide (Al2O3). A weight ratio of the silicon dioxide to the aluminum oxide in the second layer is in a range of about 25:75 to about 35:65.

In an embodiment, the second layer may be disposed directly on the first layer, and the third layer may be disposed directly on the second layer.

In an embodiment, the second layer may have a thickness in a range of about 10 nm to about 20 nm.

In an embodiment, at a wavelength of about 550 nm, the second layer may have a refractive index in a range of about 1.43 to about 1.50.

In an embodiment, at a wavelength of about 550 nm, the first layer may have a refractive index in a range of about 1.3 to about 1.5, and at a wavelength of about 550 nm, the third layer may have a refractive index in a range of about 1.2 to about 1.5.

In an embodiment, a refractive index of the first layer may be less than a refractive index of the base layer, and a refractive index of the second layer may be greater than the refractive index of the first layer.

In an embodiment, the second layer may include a solid solution in which the silicon dioxide and the aluminum oxide are mixed.

In an embodiment, at a wavelength of about 550 nm, a reflectance on an upper surface of the third layer may be about 6.0% or less.

In an embodiment, the third layer may include a fluorine-containing polymer.

In an embodiment, the base layer may include a glass substrate or a polymer film.

In an embodiment, the first layer may have a thickness in a range of about 60 nm to about 80 nm, and the third layer may have a thickness in a range of about 5 nm to about 40 nm.

In an embodiment, the window may further include a fourth layer which is disposed between the base layer and the first layer and includes magnesium oxide.

In an embodiment, the window may further include a fifth layer disposed between the base layer and the first layer. The fifth layer has a refractive index in a range of about 1.7 to about 3.0 at a wavelength of about 550 nm.

In an embodiment, the fifth layer may include at least one compound selected from the group consisting of zinc oxide (ZrO₂), hafnium oxide (HfO₂), tantalum oxide (Ta₂O₅), niobium oxide (Nb₂O₅), titanium oxide (TiO₂), ytterbium oxide (Y₂O₃), silicon nitride (Si₃N₄), strontium titanate (SrTiO₃), tungsten oxide (WO₃), and aluminum nitride (AlN).

In an embodiment, the window may further include a sixth layer disposed below the base layer. The sixth layer has a refractive index in a range of about 1.3 to about 1.5 at a wavelength of about 550 nm.

In an embodiment, the sixth layer may include at least one compound selected from the group consisting of magnesium oxide, magnesium fluoride, and yttrium oxyfluoride.

According to an embodiment of the present disclosure, a display device includes a display module and a window disposed on the display module. The window includes a base layer, a first layer disposed on the base layer, a second layer disposed on the first layer, and a third layer disposed on the second layer. The second layer includes silicon dioxide (SiO₂) and aluminum oxide (Al₂O₃). A weight ratio of the silicon dioxide to the aluminum oxide in the second layer is in a range of about 25:75 to about 35:65.

In an embodiment, the display module may include a base substrate. A circuit layer is disposed on the base substrate. A light emitting element layer is disposed on the circuit layer. The light emitting element layer includes a plurality of light emitting elements. An encapsulation layer is disposed on the light emitting element layer. An anti-reflection layer is disposed on the encapsulation layer. The anti-reflection layer may include a division layer having a plurality of division openings respectively overlapping the plurality of light emitting elements. A plurality of color filters are respectively disposed to correspond to the plurality of division openings.

In an embodiment, the first layer may be spaced apart from the display module with the base layer interposed therebetween.

In an embodiment, an upper surface of the third layer may define an outermost surface of the window.

### BRIEF DESCRIPTION OF THE DRAWINGS

The accompanying drawings are included to provide a further understanding of embodiments of the present disclosure, and are incorporated in and constitute a part of this specification. The drawings illustrate non-limiting embodiments of the present disclosure and, together with the description, serve to explain principles of the present disclosure. In the drawings:

FIG. 1A is an assembled perspective view of a display device according to an embodiment of the present disclosure;

FIG. 1B is an exploded perspective view of the display device according to an embodiment of the present disclosure;

FIG. 2 is a cross-sectional view of a display device according to an embodiment of the present disclosure;

FIG. 3 is a cross-sectional view illustrating a portion of a display module according to an embodiment of the present disclosure; and

FIGS. 4A to 4D are cross-sectional views of a window according to embodiments of the present disclosure.

### DETAILED DESCRIPTION OF EMBODIMENTS

In the present specification, when an element (or a region, a layer, a portion, etc.) is referred to as being “on,” “connected to,” or “coupled to” another element, it means that the element may be directly disposed on/connected to/coupled to the other element, or that a third element may be disposed therebetween.

Like reference numerals refer to like components throughout. Also, in the drawings, the thicknesses, ratios, and dimensions of the components may be exaggerated for convenience of description. The term “and/or” includes all of one or more combinations that can be defined by associated items.

It will be understood that, although the terms “first,” “second,” etc. may be used herein to describe various components, these components should not be limited by these terms. These terms are only used to distinguish one component from another. For example, a first component could be termed a second component, and, similarly, a second component could be termed a first component, without departing from the scope of embodiments of the present disclosure. The terms of a singular form may include plural forms unless the context clearly indicates otherwise.

In addition, terms such as “below,” “under,” “on,” and “above” may be used to describe the relationship between components illustrated in the Drawings. However, the terms are used as a relative concept and are described with reference to the direction indicated in the drawings.

It should be understood that the terms “comprise,” or “have” are intended to specify the presence of stated features, integers, steps, operations, components, parts, or combinations thereof in the specification, but do not preclude the presence or addition of one or more other features, integers, steps, operations, components, parts, or combinations thereof.

Being “disposed directly on” herein means that there are no intervening layers, films, regions, plates, or the like between a part such as a layer, a film, a region, and a plate and another part. For example, being “disposed directly on” may mean being disposed between two layers or two members without using an additional member, such as an adhesive member.

Unless otherwise defined, all terms (including technical and scientific terms) used herein have the same meaning as commonly understood by one of ordinary skill in the art to which the present disclosure belongs. In addition, it will be understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described with reference to the accompanying drawings.

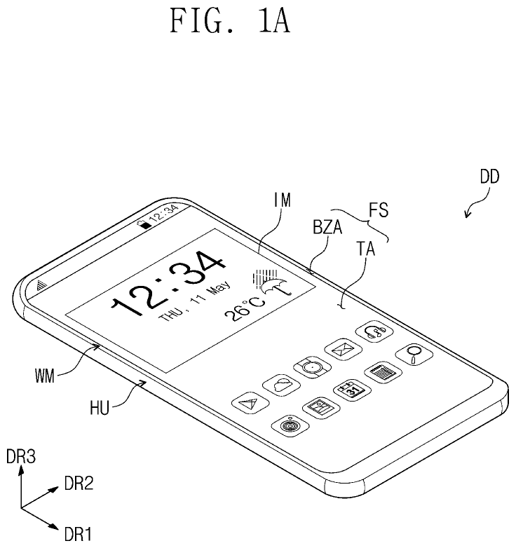

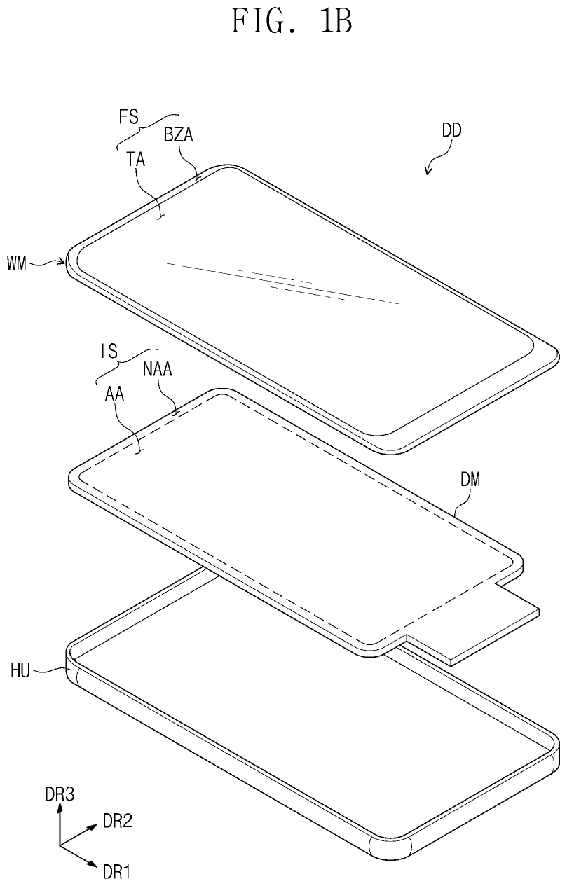

FIG. 1A is an assembled perspective view of a display device according to an embodiment of the present disclosure. FIG. 1B is an exploded perspective view of the display device according to an embodiment of the present disclosure.

Referring to FIG. 1A, the display device DD may be a device activated according to an electrical signal. For example, in an embodiment the display device DD may display an image IM and sense an external input. The display device DD may include various embodiments. For example, the display device DD may be applied to various different electronic devices. In an embodiment, the display device DD may include a tablet, a laptop, a computer, a smart television, etc. However, embodiments of the present disclosure are not necessarily limited thereto. In the embodiment shown in FIG. 1A, a smart phone is illustrated as the display device DD for convenience of explanation.

In an embodiment, the display device DD may display an image IM, toward a third direction DR3, on a display surface FS parallel to each of a first direction DR1 and a second direction DR2. The display surface FS, on which the image IM is displayed, may correspond to each of a front surface of the display device DD and a front surface FS of a window WM. Hereinafter, like reference numerals will be given for the display surface and the front surface of the display device DD, and the front surface of the window WM. The image IM may include at least one still image and/or at least one dynamic image. In the embodiment of FIG. 1A, the image IM is software application icons and a clock, temperature and calendar window. However, embodiments of the present inventive concepts are not necessarily limited thereto and the image IM may be various different subject matter.

In the present embodiment, a front surface (e.g., an upper surface in the third direction DR3) and a rear surface (e.g., a lower surface in the third direction DR3) of each member is defined with respect to a direction in which the image IM is displayed. The front and rear surfaces may be opposite to each other in the third direction DR3. A normal direction of each of the front and rear surfaces may be parallel to the third direction DR3. A spaced distance between the front and rear surfaces in the third direction DR3 may correspond to the thickness of the display panel 100 in the third direction DR3. However, the directions indicated by the first to third directions DR1, DR3, and DR3 are relative concepts, and may be converted to different directions in which the first to third directions DR1 to DR3 cross each other. Hereinafter, first to third directions refer to the same reference symbols as the directions indicated by the first and third directions DR1, DR2, and DR3, respectively. In addition, in the present specification, “on a plane” may be defined as viewed from the third direction DR3.

The display device DD according to an embodiment of the present disclosure may detect inputs from the user applied from the outside. In an embodiment, the user inputs may include various types of external inputs such as a portion of user's body, light, heat, or a pressure. The user inputs may be provided in various types, and the display device DD may sense the user's input applied to a side surface or a rear surface of the display device DD according to a structure of the display device DD in some embodiments. However, embodiment of the present disclosure are not necessarily limited thereto.

As illustrated in FIGS. 1A and 1B, the display device DD includes a window WM, a display module DM, and an outer case HU. In an embodiment, the window WM and the outer case HU are coupled to define an outer (e.g., external) appearance of the display device DD. In an embodiment, the outer case HU, the display module DM, and the window WM may be sequentially stacked in the third direction DR3.

In an embodiment, the window WM may include an optically clear material. The window WM may include an insulating panel. For example, in some embodiments the window WM may be made of glass, plastic, or a combination thereof.

As described above, the front surface FS of the window WM defines a front surface of the display device DD. The transmission region TA may be an optically clear region. For example, in an embodiment the transmission region TA may be a region having a visible light transmittance of about 90% or greater.

The bezel region BZA may have a light transmittance relatively lower than the transmission region TA. In an embodiment, the bezel region BZA may at least partially surround the transmission region TA (e.g., in the first and/or second directions DR1, DR2) to define a shape of the transmission region TA. The bezel region BZA may be adjacent to the transmission region TA.

In an embodiment, the bezel region BZA may have a certain color. The bezel region BZA may cover a peripheral region NAA of the display module DM to prevent the peripheral region NAA from being viewed from the outside. However, this is merely illustrated as an example and embodiments of the present disclosure are not necessarily limited thereto. For example, the bezel region BZA may be omitted in the window WM according to some embodiments.

The display module DM may display the image IM and sense an external input. The image IM may be displayed on the front surface IS of the display module DM. The front surface IS of the display module DM includes an active region AA and the peripheral region NAA. The active region AA may be a region that is activated according to an electrical signal.

In an embodiment, the active region AA may be a region that displays an image IM, and may be a region that senses an external input as well. The transmission region TA at least overlaps the active region AA (e.g., in the third direction DR3). For example, the transmission region TA may overlap an entire surface or at least a portion of the active region AA. Accordingly, a user may view the image IM through the transmission region TA or provide an external input. However, embodiments of the present disclosure are not necessarily limited thereto. For example, in some embodiments a region in the active region AA, on which the image IM is displayed, and a region in the active region AA, on which the external input is sensed, may be separated from each other.

The peripheral region NAA may be a region covered by the bezel region BZA. The peripheral region NAA is adjacent to the active region AA (e.g., in the first and/or second directions DR1, DR2). In an embodiment, the peripheral region NAA may at least partially surround the active region AA. A driving circuit or a driving wiring for driving the active region AA may be disposed in the peripheral region NAA.

In an embodiment, the display module DM may include a display panel and a sensor layer. The image IM may be substantially displayed in the display panel, and the external input may be substantially sensed in the sensor layer. The display module DM may include both the display panel and the sensor layer, and thus may sense the external input while displaying the image IM. This will be described later in detail.

The display device DD according to an embodiment may further include a driving circuit. In an embodiment, the driving circuit may include a flexible circuit board and a main circuit board. The flexible circuit board may be electrically connected to the display module DM. The flexible circuit board may connect the display module DM with the main circuit board. However, embodiments of the present disclosure are not necessarily limited thereto. For example, the flexible circuit board according to an embodiment of the present disclosure may not be connected to the main circuit board, and the flexible circuit board may be a rigid board.

In an embodiment, the flexible circuit board may be connected to pads of the display module DM disposed in the peripheral region NAA. The flexible circuit board may provide an electrical signal for driving the display module DM to the display module DM. The electrical signal may be generated in the flexible circuit board or in the main circuit board. In an embodiment, the main circuit board may include various driving circuits for driving the display module DM, connectors for supplying power, or the like. The main circuit board may be connected to the display module DM through the flexible circuit board.

Although FIG. 1B illustrates a state in which the display module DM is unfolded, at least a portion of the display module DM may be bent. For example, in an embodiment, a portion of the display module DM may be bent towards the rear surface of the display module DM, and a portion of the display module DM bent towards the rear surface may be a portion to which the main circuit board is connected. Accordingly, the main circuit board may be assembled in a state overlapping the rear surface of the display module DM (e.g., in the third direction DR3).

The outer case HU is coupled to the window WM to define an outer appearance (e.g., an external appearance) of the display device DD. The outer case HU provides a predetermined inner space. The display module DM may be accommodated in the inner space.

In an embodiment, the outer case HU may include a material having a relatively high rigidity. For example, in an embodiment the outer case HU may include a plurality of frames and/or plates including glass, plastic, or metal, or a combination thereof. The outer case HU may stably protect the components of the display device DD accommodated in the inner space from external impact.

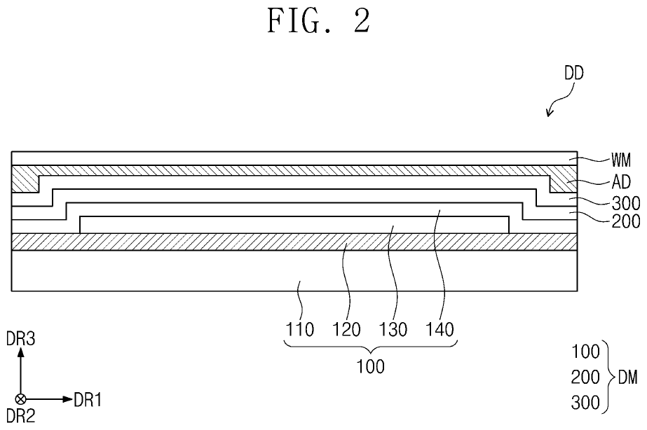

FIG. 2 is a cross-sectional view of a display device according to an embodiment of the present disclosure.

Referring to FIG. 2, the display device DD may include a display module DM and a window WM. In an embodiment, the display module DM and the window WM may be coupled together via an adhesive layer AD. In the display device DD of an embodiment, the display module DM may include a display panel 100, a sensor layer 200, and an anti-reflection layer 300. In an embodiment, the anti-reflection layer 300 among the plurality of layers in the display module DM may be coupled to the window WM via the adhesive layer AD.

The display panel 100 may be a component that substantially generates an image, such as the image IM shown in FIG. 1A. In an embodiment, the display panel 100 may be an emission-type display panel. For example, in an embodiment the display panel 100 may be an organic light emitting display panel, an inorganic light emitting display panel, a micro LED display panel, or a nano LED display panel. However, embodiments of the present disclosure are not necessarily limited thereto. The display panel 100 may be referred to as a display layer.

In an embodiment, the display panel 100 may include a base substrate 110, a circuit layer 120, a light emitting element layer 130, and an encapsulation layer 140.

The base substrate 110 may be a member that provides a base surface on which a circuit layer 120 is disposed. The base substrate 110 may be a rigid substrate or a flexible substrate that is bendable, foldable, rollable, or the like. For example, in an embodiment the base substrate 110 may be a glass substrate, a metal substrate, a polymer substrate, or the like. However, embodiments of the present disclosure are not necessarily limited thereto. For example, the base substrate 110 may be an inorganic layer, an organic layer, or a composite material layer in some embodiments.

In an embodiment, the base substrate 110 may have a multi-layered structure. For example, the base substrate 110 may include a first synthetic resin layer, a multi-layered or single-layered inorganic layer, and a second synthetic resin layer disposed on the multi-layered or single-layered inorganic layer. Each of the first and second synthetic resin layers may include a polyimide-based resin. However, embodiments of the present disclosure are not necessarily limited thereto.

The circuit layer 120 may be disposed on the base substrate 110 (e.g., disposed directly thereon in the third direction DR3). In an embodiment, the circuit layer 120 may include an insulation layer, a semiconductor pattern, a conductive pattern, and a signal line.

The light emitting element layer 130 may be disposed on the circuit layer 120 (e.g., disposed directly thereon in the third direction DR3). The light emitting element layer 130 may include a plurality of light emitting elements. For example, in an embodiment the light emitting element may include an organic light emitting material, an inorganic light emitting material, an organic-inorganic light emitting material, quantum dots, quantum rods, a micro LED, or a nano LED. However, embodiments of the present disclosure are not necessarily limited thereto.

The encapsulation layer 140 may be disposed on the light emitting element layer 130 (e.g., disposed directly thereon). The encapsulation layer 140 may protect the light emitting element layer 130 against foreign substances such as moisture, oxygen, and dust particles. The encapsulation layer 140 may include at least one inorganic layer. For example, in an embodiment the encapsulation layer 140 may include a stacked structure of an inorganic layer/organic layer/inorganic layer. However, embodiments of the present disclosure are not necessarily limited thereto. For example, the encapsulation layer 140 may include at least one organic layer and at least one inorganic layer in some embodiments.

The sensor layer 200 may be disposed on the display panel 100. The sensor layer 200 may sense external inputs applied from the outside. For example, the external inputs may be user inputs. In an embodiment, the user inputs may include various types of external inputs such as a part of a user's body, light, heat, pen, or pressure.

In an embodiment, the sensor layer 200 may be disposed on the display panel 100 through a continuous process. In this case, the sensor layer 200 may be disposed directly on the display panel 100 (e.g., in the third direction DR3). Here, being “disposed directly on” may mean that a third component is not disposed between the sensor layer 200 and the display panel 100. For example, a separate adhesive member may not be disposed between the sensor layer 200 and the display panel 100.

In an embodiment, the anti-reflection layer 300 may be disposed directly on the sensor layer 200 (e.g., in the third direction DR3). The anti-reflection layer 300 may reduce reflectance of external light incident from the outside of the display device DD. The anti-reflection layer 300 may be disposed on the sensor layer 200 through a continuous process. In an embodiment, the anti-reflection layer 300 may include color filters. The color filters may have a predetermined arrangement. For example, in an embodiment the color filters may be arranged in consideration of emission colors of the pixels included in the display panel 100. Also, the anti-reflection layer 300 may further include a black matrix adjacent to the color filters. The detailed description of the anti-reflection layer 300 will be described later.

In an embodiment of the present disclosure, the sensor layer 200 may be omitted. In this embodiment, the anti-reflection layer 300 may be disposed directly on the display panel 100 (e.g., in the third direction DR3). In an embodiment of the present disclosure, the positions of the sensor layer 200 and the anti-reflection layer 300 may be switched.

In an embodiment of the present disclosure, the display device DD may further include an optical layer disposed on (e.g., disposed above) the anti-reflection layer 300. For example, in an embodiment the optical layer may be disposed on the anti-reflection layer 300 through a continuous process. The optical layer may control the direction of the light incident from the display panel 100 to increase the front brightness of the display device DD. For example, in an embodiment the optical layer may include an organic insulation layer in which openings are defined respectively corresponding to light emitting regions of pixels included in the display panel 100, and a high refractive layer covering the organic insulation layer and filling the openings. The high refractive layer may have a refractive index higher than that of the organic insulation layer.

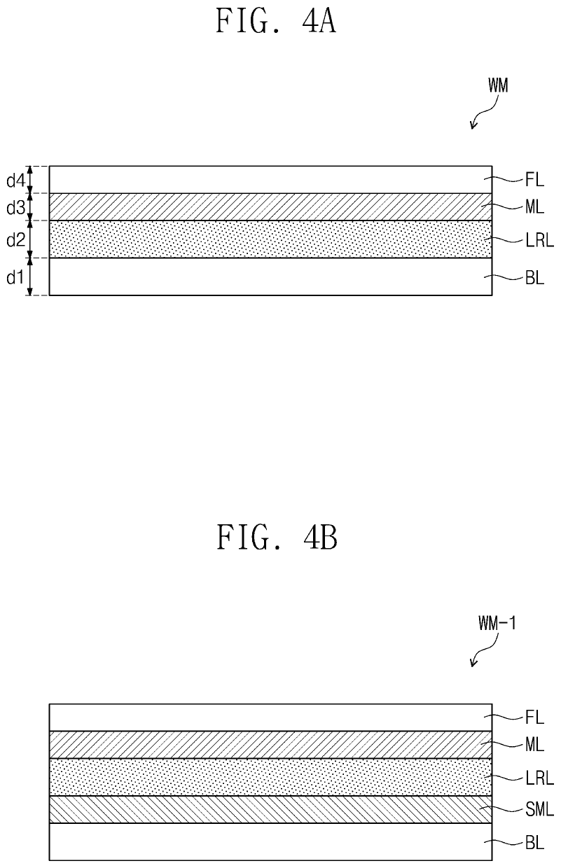

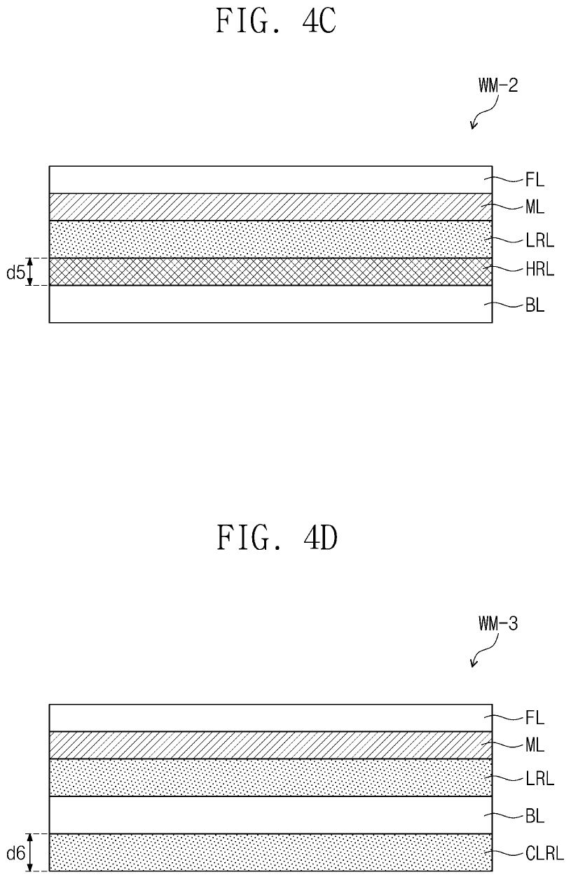

The window WM may provide a front surface of the display device DD. In an embodiment, the window WM may include a glass film or a synthetic resin film as a base film. In an embodiment, the window WM may further include functional layers such as an anti-reflection layer and an anti-fingerprint layer. The description of the functional layers included in the window WM will be described in more detail in the description of FIGS. 4A to 4D. In an embodiment, the window WM may further include a bezel pattern overlapping the above-described bezel region BZA in the third direction DR3 (see FIG. 1B).

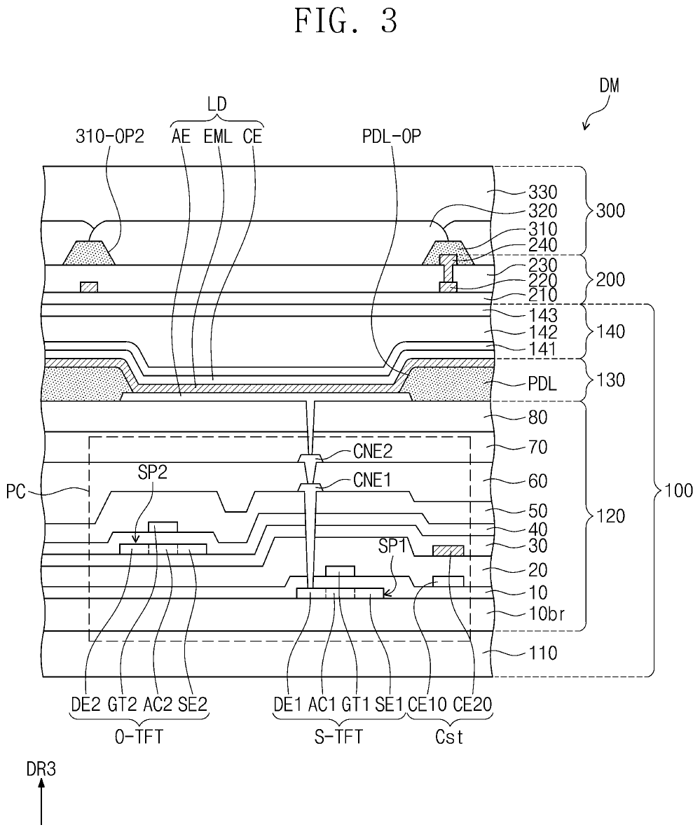

FIG. 3 is a cross-sectional view illustrating a portion of a display module according to an embodiment of the present disclosure. FIG. 3 illustrates a partial cross-sectional view of a single light emitting element LD and a single pixel circuit PC included in a display module DM.

A display panel 100 included in the display module DM of an embodiment may include a base substrate 110. The base substrate 110 may be a member that provides a base surface on which a circuit layer 120 is disposed. In an embodiment, the base substrate 110 may be a glass substrate, a metal substrate, a plastic substrate, a silicone substrate, or the like. However, embodiments of the present disclosure are not necessarily limited thereto, and the base substrate 110 may be an inorganic layer, an organic layer, or a composite material layer in some embodiments.

A buffer layer 10br may be disposed on the base substrate 110 (e.g., disposed directly thereon in the third direction DR3). In an embodiment, the buffer layer 10br may prevent metal atoms or impurities from diffusing from the base substrate 110 to a first semiconductor pattern SP1 thereabove. The first semiconductor pattern SP1 includes a channel region AC1 of a silicon transistor S-TFT. The buffer layer 10br may adjust a heat supply speed during a crystallization process for forming the first semiconductor pattern SP1, thereby uniformly forming the first semiconductor pattern SP1.

The first semiconductor pattern SP1 may be disposed on the buffer layer 10br (e.g., disposed directly thereon in the third direction DR3). In an embodiment, the first semiconductor pattern SP1 may include a silicon semiconductor. For example, in an embodiment the silicon semiconductor may include amorphous silicon, polycrystalline silicon, or monocrystalline silicon. For example, the first semiconductor pattern SP1 may include a low-temperature polysilicon. However, embodiments of the present disclosure are not necessarily limited thereto.

FIG. 3 merely illustrates a portion of the first semiconductor pattern SP1 disposed on the buffer layer 10br, and the first semiconductor pattern SP1 may be further disposed in other regions. The first semiconductor pattern SP1 may be arranged in a specific rule over the pixels. The first semiconductor pattern SP1 may differ in electrical properties depending on whether or not the semiconductor pattern SP1 is doped. For example, in an embodiment the first semiconductor pattern SP1 may include a first region having high conductivity and a second region having low conductivity. The first region may be doped with an N-type dopant or a P-type dopant. A P-type transistor may include a doped region doped with the P-type dopant, and an N-type transistor may include a doped region doped with the N-type dopant. The second region may be a non-doped region or may be a region that is doped at a concentration less than that of the first region.

The first region may have conductivity greater than the second region and may substantially serve as an electrode or a signal line. The second region may substantially correspond to an active region (e.g., a channel) of the transistor. For example, one portion of the first semiconductor pattern SP1 may be the active region of the transistor, another portion may be a source or a drain of the transistor, and another portion may be a connection electrode or a connection signal line.

A source region SE1 (e.g., a source), a channel region AC1 (e.g., a channel), and a drain region DE1 (e.g., a drain) of the silicon transistor S-TFT may be disposed from the first semiconductor pattern SP1. The source region SE1 and the drain region DE1 may extend in opposite directions from the channel region AC1 on a cross-section.

In an embodiment, a rear metal layer may be disposed under each of the silicon transistor S-TFT and an oxide transistor O-TFT. The rear metal layer may be disposed to overlap the pixel circuit PC (e.g., in the third direction DR3), and may block external light from reaching the pixel circuit PC. The rear metal layer may be disposed between the base substrate 110 and the buffer layer 10br (e.g., in the third direction DR3). However, embodiments of the present disclosure are not necessarily limited thereto. For example, in an embodiment the rear metal layer may be disposed between a second insulation layer 20 and a third insulation layer 30 (e.g., in the third direction DR3). The rear metal layer may include a reflective metal. For example, in an embodiment the rear metal layer may include silver (Ag), an alloy containing silver (Ag), molybdenum (Mo), an alloy containing molybdenum, aluminum (Al), an alloy containing aluminum, aluminum nitride (AlN), tungsten (W), tungsten nitride (WN), copper (Cu), p+ doped amorphous silicon, or the like. The rear metal layer may be connected to an electrode or wiring and may receive a constant voltage or signal therefrom. According to an embodiment of the present disclosure, the rear metal layer may be a floating electrode which is isolated from another electrode or wiring. In an embodiment of the present disclosure, an inorganic barrier layer may be further disposed between the base substrate 110 and the buffer layer 10br (e.g., in the third direction DR3).

The first insulation layer 10 may be disposed on the buffer layer 10br (e.g., disposed directly thereon in the third direction DR3). The first insulation layer 10 commonly overlaps the plurality of pixels, and may cover the first semiconductor pattern SP1. The first insulation layer 10 may be an inorganic layer and/or an organic layer and have a single-layered or multi-layered structure. For example, in an embodiment the first insulation layer 10 may include at least one of aluminum oxide, titanium oxide, silicon oxide, silicon nitride, silicon oxynitride, zirconium oxide, or hafnium oxide. In this embodiment, the first insulation layer 10 may include a single-layered silicon oxide layer. The insulation layer of the circuit layer 120, which will be described later, as well as the first insulation layer 10 may be an inorganic layer and/or an organic layer and may have a single-layered or multilayered structure. The inorganic layer may include at least one of the above-described materials. However, embodiments of the present disclosure are not necessarily limited thereto.

A gate GT1 of the silicon transistor S-TFT is disposed on the first insulation layer 10 (e.g., disposed directly thereon in the third direction DR3). The gate GT1 may be a portion of a metal pattern. The gate GT1 overlaps the channel region AC1 (e.g., in the third direction DR3). In the process in which the semiconductor pattern SP1 is doped, the gate GT1 may function as a mask. In an embodiment, the gate GT1 may include titanium (Ti), silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), indium tin oxide (ITO), indium zinc oxide (IZO), or the like. However, embodiments of the present disclosure are not necessarily limited thereto.

The second insulation layer 20 may be disposed on the first insulation layer 10 (e.g., in the third direction DR3) to cover the gate GT1. A third insulation layer 30 may be disposed on the second insulation layer 20 (e.g., in the third direction DR3). A second electrode CE20 of a storage capacitor Cst may be disposed between the second insulation layer 20 and the third insulation layer 30. In addition, the first electrode CE10 of the storage capacitor Cst may be disposed between the first insulation layer 10 and the second insulation layer 20.

A second semiconductor pattern SP2 may be disposed on the third insulation layer 30 (e.g., disposed directly thereon in the third direction DR3). The second semiconductor pattern SP2 may include a channel region AC2 of the oxide transistor O-TFT, which will be described later. The second semiconductor pattern SP2 may include an oxide semiconductor. In an embodiment, the second semiconductor pattern SP2 may include a transparent conductive oxide (TCO) such as indium tin oxide (ITO), indium zinc oxide (IZO), indium gallium zinc oxide (IGZO), zinc oxide (ZnO), or indium oxide (In₂O₃). However, embodiments of the present disclosure are not necessarily limited thereto.

The oxide semiconductor may include a plurality of regions divided according to whether the transparent conductive oxide is reduced. The region in which the transparent conductive oxide is reduced (hereinafter, referred to as a reduction region) has a greater conductivity than the region in which the transparent conductive oxide is not reduced (hereinafter, referred to as a non-reduction region). The reduction region substantially serves as a source/drain or signal line of the transistor. The non-reduction region substantially corresponds to a semiconductor region (e.g., an active region or channel) of the transistor. For example, a partial region of the second semiconductor pattern SP2 may be a semiconductor region of the transistor, another partial region may be a source region/drain region of the transistor, and another partial region may be a signal transfer region.

The source region SE2 (e.g., a source), the channel region AC2 (e.g., a channel), and the drain region DE2 (e.g., a drain) of the oxide transistor O-TFT may be disposed from the second semiconductor pattern SP2. The source region SE2 and the drain region DE2 may extend in opposite directions from the channel region AC2 on a cross-section.

A fourth insulation layer 40 may be disposed on the third insulation layer 30 (e.g., in the third direction DR3). The fourth insulation layer 40 commonly overlaps the plurality of pixels, and may cover the second semiconductor pattern SP2. In an embodiment, the fourth insulation layer 40 may be provided in the form of an insulation pattern overlapping a gate GT2 of the oxide transistor O-TFT and exposing the source region SE2 and the drain region DE2 of the oxide transistor O-TFT.

The gate GT2 of the oxide transistor O-TFT is disposed on the fourth insulation layer 40. The gate GT2 of the oxide transistor O-TFT may be a portion of a metal pattern. The gate GT2 of the oxide transistor O-TFT overlaps the channel region AC2 (e.g., in the third direction DR3).

A fifth insulation layer 50 may be disposed on the fourth insulation layer 40 (e.g., in the third direction DR3) and may cover the gate GT2. A first connection electrode CNE1 may be disposed on the fifth insulation layer 50 (e.g., disposed directly thereon in the third direction DR3). In an embodiment, the first connection electrode CNE1 may be connected to the drain region DE1 of the silicon transistor S-TFT through a contact hole passing through the first to fifth insulation layers 10, 20, 30, 40, and 50.

A sixth insulation layer 60 may be disposed on the fifth insulation layer 50 (e.g., disposed directly thereon in the third direction DR3). A second connection electrode CNE2 may be disposed on the sixth insulation layer 60 (e.g., disposed directly thereon in the third direction DR3). In an embodiment, the second connection electrode CNE2 may be connected to the first connection electrode CNE1 through a contact hole passing through the sixth insulating layer 60. A seventh insulation layer 70 may be disposed on the sixth insulation layer 60 (e.g., in the third direction DR3) to cover the second connection electrode CNE2. An eighth insulation layer 80 may be disposed on the seventh insulation layer 70 (e.g., disposed directly thereon in the third direction DR3).

In an embodiment, each of the sixth insulation layer 60, the seventh insulation layer 70, and the eighth insulation layer 80 may be an organic layer. For example, in an embodiment each of the sixth insulation layer 60, the seventh insulation layer 70, and the eighth insulation layer 80 may include a general-purpose polymer such as benzocyclobutene (BCB), polyimide, hexamethyldisiloxane (HMDSO), polymethylmethacrylate (PMMA), or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, a blend thereof, or the like.

The light emitting element LD may include a first electrode AE (e.g., a pixel electrode), an emission layer EML, and a second electrode CE (e.g., a common electrode). Each of the emission layer EML and the second electrode CE may be commonly disposed in a plurality of pixels.

The first electrode AE of the light emitting element LD may be disposed on the eighth insulation layer 80 (e.g., disposed directly thereon in the third direction DR3). The first electrode AE of the light emitting element LD may be a transmissive electrode, a transflective electrode, or a reflective electrode. According to an embodiment of the present disclosure, the first electrode AE of the light emitting element LD may include a reflective layer formed of Ag, Mg, Al, Pt, Pd, Au, Ni, Nd, Ir, Cr, or a compound thereof, and a transparent or translucent electrode layer formed on the reflective layer. In an embodiment, the transparent or translucent electrode layer may include at least one selected from the group consisting of indium tin oxide (ITO), indium zinc oxide (IZO), indium gallium zinc oxide (IGZO), zinc oxide (ZnO), or indium oxide (In₂O₃), and aluminum-doped zinc oxide (AZO). For example, the first electrode AE of the light emitting element LD may include a stacked structure of ITO/Ag/ITO.

The pixel defining film PDL may be disposed on the eighth insulation layer 80 (e.g., disposed directly thereon in the third direction DR3). In an embodiment, the pixel defining film PDL may include a same material and may be formed through the same process. The pixel defining film PDL may have a property of absorbing light, and for example, the pixel defining film PDL may have a black color. For example, the pixel defining film PDL may include a black coloring agent. The black coloring agent may include a black dye and a black pigment. In an embodiment, the black coloring agent may include carbon black, a metal such as chromium, or an oxide thereof. The pixel defining film PDL may correspond to a light shielding pattern having a light shielding characteristic.

The pixel defining film PDL may cover a portion of the first electrode AE of the light emitting element LD. For example, an opening PDL-OP for exposing a portion of the first electrode AE of the light emitting element LD may be defined in the pixel defining film PDL. For example, a shown in FIG. 3 in an embodiment the pixel defining film PDL may cover lateral ends of the first electrode AE and the opening PDL-OP may expose a central portion of the first electrode AE. However, embodiments of the present disclosure are not necessarily limited thereto. The pixel defining film PDL may increase the distance between the edge of the first electrode AE of the light emitting element LD and the second electrode CE. Accordingly, an arc or the like may be prevented from being generated at the edges of the first electrodes AE by the pixel defining film PDL.

In an embodiment, a hole control layer may be disposed between the first electrode AE and the emission layer EML (e.g., in the third direction DR3). In an embodiment, the hole control layer may include a hole transport layer and may further include a hole injection layer. An electron control layer may be disposed between the emission layers EML and the second electrode CE (e.g., in the third direction DR3). In an embodiment, the electron control layer may include an electron transport layer and may further include an electron injection layer. The hole control layer and the electron control layer may be commonly formed in the plurality of pixels by using an open mask.

The encapsulation layer 140 may be disposed on the light emitting element layer 130 (e.g., in the third direction DR3). In an embodiment, the encapsulation layer 140 may include an inorganic layer 141, an organic layer 142, and an inorganic layer 143 stacked sequentially (e.g., in the third direction DR3), but layers constituting the encapsulation layer 140 are not necessarily limited thereto.

The inorganic layers 141 and 143 may protect the light emitting element layer 130 against moisture and oxygen, and the organic layer 142 may protect the light emitting element layer 130 against foreign substances such as dust particles. In an embodiment, the inorganic layers 141 and 143 may include a silicon nitride layer, a silicon oxynitride layer, a silicon oxide layer, a titanium oxide layer, an aluminum oxide layer, or the like. The organic layer 142 may include an acrylic-based organic layer. However, embodiments of the present disclosure are not necessarily limited thereto.

In an embodiment, the sensor layer 200 may be disposed on the display panel 100 (e.g., in the third direction DR3). The sensor layer 200 may be referred to as a sensor, an input sensing layer, or an input sensing panel. In an embodiment, the sensor layer 200 may include a sensor base layer 210, a first conductive layer 220, a sensing insulation layer 230, and a second conductive layer 240.

In an embodiment, the sensor base layer 210 may be disposed directly on the display panel 100 (e.g., in the third direction DR3). In an embodiment, the sensor base layer 210 may be an inorganic layer including at least one of silicon nitride, silicon oxynitride, or silicon oxide. Alternatively, the sensor base layer 210 may be an organic layer including an epoxy resin, an acrylic resin, or an imide-based resin. The sensor base layer 210 may have a single-layered structure or a multi-layered structure stacked in the third direction DR3.

Each of the first conductive layer 220 and the second conductive layer 240 may have a single-layered structure or a multi-layered structure stacked in the third direction DR3. The first conductive layer 220 and the second conductive layer 240 may include conductive lines defining mesh-shaped sensing electrodes. The conductive lines may not overlap the opening PDL-OP (e.g., in the third direction DR3), but may overlap the pixel defining film PDL (e.g., in the third direction DR3).

In an embodiment, the single-layered conductive layer may include a metal layer or a transparent conductive layer. The metal layer may include molybdenum, silver, titanium, copper, aluminum, or an alloy thereof. The transparent conductive layer may include transparent conductive oxide such as indium tin oxide (ITO), indium zinc oxide (IZO), zinc oxide (ZnO), indium zinc tin oxide (IZTO), or the like. In addition, the transparent conductive layer may include a conductive polymer such as PEDOT, a metal nanowire, graphene, etc. However, embodiments of the present disclosure are not necessarily limited thereto.

The conductive layer having the multi-layered structure may include metal layers. In an embodiment, the metal layers may have a three-layered structure of titanium/aluminum/titanium. The conductive layer having the multi-layered structure may include at least one metal layer and at least one transparent conductive layer.

The sensing insulation layer 230 may be disposed between the first conductive layer 220 and the second conductive layer 240. In an embodiment, the sensing insulation layer 230 may include an inorganic film. For example, the inorganic film may include at least one of aluminum oxide, titanium oxide, silicon oxide, silicon nitride, silicon oxynitride, zirconium oxide, or hafnium oxide. However, embodiments of the present disclosure are not necessarily limited thereto.

Alternatively, the sensing insulation layer 230 may include an organic film. For example, the organic film may include at least any one among an acrylic-based resin, a methacrylic-based resin, polyisoprene, a vinyl-based resin, an epoxy-based resin, a urethane-based resin, a cellulose-based resin, a siloxane-based resin, a polyimide-based resin, a polyamide-based resin, and a perylene-based resin. However, embodiments of the present disclosure are not necessarily limited thereto.

In an embodiment, the anti-reflection layer 300 may be disposed on the sensor layer 200 (e.g., disposed directly thereon in the third direction DR3). In an embodiment, the anti-reflection layer 300 may include a division layer 310, a plurality of color filters 320, and a planarization layer 330.

The anti-reflection layer 300 may reduce the reflectance of the external light. The anti-reflection layer 300 may include the plurality of color filters 320, and the plurality of color filters 320 may have a predetermined arrangement. For example, the arrangement of the plurality of color filters 320 may be determined in consideration of emission colors of pixels included in the display panel 100. In the display module DM of an embodiment, the anti-reflection layer 300 may not include a phase retarder and a polarizer, and may reduce the reflectance of the display module DM through the plurality of color filters 320. In the display module DM of an embodiment, the anti-reflection layer 300 may not include a polarizing film or a polarizing layer.

A material constituting the division layer 310 is not specifically limited as long as it is a material that absorbs light. In an embodiment, the division layer 310 is a black layer. For example, the division layer 310 may include a black coloring agent. The black coloring agent may include a black dye and a black pigment. For example, the black coloring agent may include carbon black, a metal such as chromium, or an oxide thereof.

The division layer 310 may cover the second conductive layer 240 of the sensor layer 200. The division layer 310 may prevent the external light reflection by the second conductive layer 240. The division layer 310 may overlap a portion of the pixel defining film PDL (e.g., in the third direction DR3).

In an embodiment, at least one division opening 310-OP2 may be defined in the division layer 310. For example, the division layer 310 may include a plurality of division openings 310-OP2. Each of the plurality of division openings 310-OP2 may overlap a light emitting element LD of the plurality of light emitting elements LD, such as the first electrode AE of the light emitting element LD (e.g., in the third direction DR3). Any one among the plurality of color filters 320 may overlap the first electrode AE of the light emitting element LD. Any one among the plurality of color filters 320 may cover the division opening 310-OP2. For example, the plurality of color filters 320 may be respectively disposed to correspond to a plurality of division openings 310-OP2. Each of the plurality of color filters 320 may be in direct contact with the division layer 310.

The planarization layer 330 may cover the division layer 310 and the plurality of color filters 320. In an embodiment, the planarization layer 330 may include an organic material, and a flat surface may be provided in the upper surface of the planarization layer 330. However, embodiments of the present disclosure are not necessarily limited thereto. For example, in an embodiment the planarization layer 330 may be omitted.

Each of FIGS. 4A to 4D is a cross-sectional view of a window according to embodiments of the present disclosure.

Referring to FIG. 4A, the window WM according to an embodiment of the present disclosure includes a base layer BL, a first layer LRL, a second layer ML, and a third layer FL. In the window WM according to an embodiment as shown in FIG. 4A, the base layer BL, the first layer LRL, the second layer ML, and the third layer FL may be sequentially stacked (e.g., in the third direction DR3).

The base layer BL may include a transparent material. For example, in an embodiment, the base layer BL may include a glass, a tempered glass, or a polymer film. In an embodiment, the base layer BL may be a chemically strengthened glass substrate. In an embodiment in which the base layer BL is a chemically strengthened glass substrate, the base layer BL may be relatively thin and increase mechanical strength, and thus may be used as a window of a foldable display device. In an embodiment in which the base layer BL includes a polymer film, the base layer BL may include a polyimide (Pl) film or a polyethylene terephthalate (PET) film.

The base layer BL of the window WM may have a multi-layered structure or a single-layered structure. For example, in an embodiment the base layer BL may have a structure in which a plurality of polymer films are coupled to each other via an adhesive member, or may have a structure in which the glass substrate and the polymer film are coupled to each other by means of an adhesive. The base layer BL may be made of a flexible material.

In an embodiment, the thickness d1 of the base layer BL (e.g., length in the third direction DR3) may be, for example, in a range of about 20 μm to about 60 μm. For example, in an embodiment the thickness d1 of the base layer BL may be in a range of about 20 μm to about 40 μm. Although FIGS. 4A and 4B illustrate that the base layer BL has a rectangular shape, the base layer BL is not necessarily limited thereto. For example, in an embodiment the base layer BL may have a shape in which a lateral edge portion of an upper surface of the base layer BL is rounded by a curved surface. For example, the base layer BL may have a shape in which an edge portion of the upper surface overlapping the bezel region BZA (see FIG. 1B) is rounded by a curved surface.

The first layer LRL is a layer having a refractive index lower than the refractive index of the base layer BL, and may be a layer for lowering the surface reflectance of the window WM. The first layer LRL may be disposed on the base layer BL (e.g., in the third direction DR3). The first layer LRL may be a layer disposed directly on the base layer BL. For example, the first layer LRL may be disposed on the upper surface of the base layer BL, and a lower surface of the base layer BL may be a surface adjacent to the above-described display module DM (see FIG. 2). For example, the first layer LRL may be spaced apart from the display module DM with the base layer BL interposed therebetween (e.g., in the third direction DR3).

The first layer LRL may include a material having a low refractive index and a high adhesion to the base layer BL. In an embodiment, the first layer LRL may include a first material, and the first material may include a material having a lower refractive index than the refractive index of the material included in the base layer BL. In an embodiment, the first material included in the first layer LRL may include, for example, at least one of silicon dioxide, molten silicon dioxide, fluorine-doped molten silicon dioxide, magnesium fluoride (MgF₂), calcium fluoride (CaF₂), aluminum fluoride (AlF₃), yttrium fluoride (YF₃), ytterbium fluoride (YbF₃), aluminum oxide (Al₂O₃), or magnesium oxide (MgO). For example, the first layer LRL may include at least one of magnesium fluoride (MgF₂) or magnesium oxide (MgO) as the first material.

In an embodiment, the first layer LRL may include magnesium fluoride (MgF₂). For example, the first layer LRL may be a single layer made of magnesium fluoride.

Alternatively, the first layer LRL may further include magnesium oxide (MgO) and yttrium oxyfluoride (YOF) in addition to magnesium fluoride. In an embodiment, the first layer LRL may include a solid solution containing magnesium oxide in the structure. For example, the first layer LRL may include, for example, a solid solution in which magnesium oxide, magnesium fluoride, and yttrium oxyfluoride are mixed.

The thickness d2 (e.g., length in the third direction DR3) of the first layer LRL may be, for example, in a range of about 50 nm to about 90 nm. For example, in an embodiment the thickness d2 of the first layer LRL may be in a range of about 60 nm to about 80 nm. In a comparative embodiment in which the thickness d2 of the first layer LRL is less than about 50 nm, the surface reflectance of the window WM may not be sufficiently reduced. In a comparative embodiment in which the thickness d2 of the first layer LRL is greater than about 90 nm, the total thickness of the window WM may be increased so that the total thickness of the display device may be increased excessively.

In an embodiment, at a wavelength of about 550 nm, the first layer LRL may have a refractive index of about 1.5 or less. For example, at a wavelength of about 550 nm, the first layer LRL may have a refractive index in a range of about 1.3 to about 1.5. In the window WM of an embodiment, at a wavelength of about 550 nm, the first layer LRL may have a refractive index in a range of about 1.38 to about 1.40. As the refractive index of the first layer LRL satisfies the above range at a wavelength of about 550 nm, the surface reflectance of the window WM may be reduced.

In an embodiment, the first layer LRL may be formed by an ion-assisted deposition process. For example, in an embodiment he first layer LRL may be formed of magnesium oxide, magnesium fluoride, and yttrium oxyfluoride, as described above. In the process of forming the first layer LRL, each of magnesium oxide, magnesium fluoride, and yttrium oxyfluoride is deposited on the surface of the base layer BL in the form of a particle, while an ionized argon (Ar) gas or oxygen (O₂) gas is provided together during the deposition process, so that the adhesion of the deposition film to the surface of the base layer BL may be increased. Alternatively, the first layer LRL may be formed of a magnesium fluoride single material, and the magnesium fluoride may be deposited on the surface of the base layer BL in the form of a particle, while an ionized argon (Ar) gas or oxygen (O₂) gas is provided together during the deposition process, so that the adhesion of the deposition film to the surface of the base layer BL may be increased.

In an embodiment, the first layer LRL may have a single-layered structure formed of a single material. The first layer LRL may be a single layer formed of magnesium fluoride, or a single layer formed of a solid solution in which magnesium oxide, magnesium fluoride, and yttrium oxyfluoride are mixed, as described above. For example, the first layer LRL may not include a plurality of layers.

The second layer ML may be disposed on the first layer LRL (e.g., disposed directly thereon in the third direction DR3), and may be a layer for increasing adhesion between the first layer LRL and the third layer FL. The second layer ML may have a high adhesion to each of the first layer LRL and the third layer FL, and may be an adhesion promoter which increases interlayer adhesion between the first layer LRL and the third layer FL. In addition, the second layer ML may be disposed on the first layer LRL to increase chemical resistance, scratch resistance, and abrasion resistance of the window WM. In an embodiment, the second layer ML may be disposed directly on the first layer LRL.

The second layer ML may have a high mechanical strength and may include a material for increasing adhesion. In an embodiment, the second layer ML may include silicon dioxide (SiO₂) and aluminum oxide (Al₂O₃). The content of the aluminum oxide (Al₂O₃) included in the second layer ML is greater than the content of the silicon dioxide (SiO₂) included in the second layer ML. In an embodiment, the weight ratio of the silicon dioxide (SiO₂) and the aluminum oxide (Al₂O₃) in the second layer ML may be in a range of about 25:75 to about 35:65. For example, the weight ratio of the silicon dioxide (SiO₂) and the aluminum oxide (Al₂O₃) may satisfy Expressions 1 to 3 below:

$$25 \leq a \leq 35 \qquad [ Expression 1 ]$$

$$65 \leq b \leq 75 \qquad [ Expression 2 ]$$

$$a + b = 100 \qquad [ Expression 3 ]$$

In Expressions 1 to 3, “a” means a weight ratio of silicon dioxide (SiO₂) in the second layer (ML), and “b” means a weight ratio of aluminum oxide (Al₂O₃). In an embodiment in which the weight ratio of the silicon dioxide (SiO₂) and the aluminum oxide (Al₂O₃) in the second layer ML satisfies the above-described range, both the optical characteristics and the mechanical durability of the window WM may be increased

The second layer ML may be disposed between the first layer LRL and the third layer FL to function to increase the adhesive strength between the first layer LRL and the third layer FL. In addition, the second layer ML may function to increase abrasion resistance and scratch resistance while increasing the surface hardness of the window WM.

The conventional thin film including only silicon dioxide (SiO₂) has a limitation in that the durability against thermal shock and stress is weak. However, a method for forming a thin film by mixing silicon dioxide (SiO₂) with a metal oxide such as aluminum oxide (Al₂O₃) has been studied to increase the thermal shock and durability. In an embodiment in which aluminum oxide (Al₂O₃) is mixed with silicon dioxide (SiO₂), the effects of increasing adhesion between layers, increasing thin film hardness, and increasing friction durability may be exhibited, but the above-described effects may vary greatly with the content composition ratio of silicon dioxide (SiO₂) and aluminum oxide (Al₂O₃). In an embodiment of the present disclosure, the composition ratio of the silicon dioxide (SiO₂) and the aluminum oxide (Al₂O₃) included in the second layer (ML) is applied within the above-described range, thereby increasing the adhesion between layers and maximizing the effects of hardness, abrasion resistance, scratch resistance, and the like.

In an embodiment, the second layer ML may include a solid solution containing silicon dioxide (SiO₂) and aluminum oxide (Al₂O₃). The second layer ML may include, for example, a solid solution in which silicon dioxide (SiO₂) and aluminum oxide (Al₂O₃) are mixed.

In an embodiment, silicon dioxide (SiO₂) and aluminum oxide (Al₂O₃) may be present as a substituted solid solution in the second layer ML. For example, a second material included in the second layer ML may have a solid solution structure containing AlSiO₅.

In an embodiment, the second layer ML may have a single-layered structure formed of a single material. As described above, the second layer ML may be a single layer formed of a solid solution in which magnesium oxide and silicon dioxide are mixed, or a single layer formed of a solid solution in which aluminum oxide and silicon dioxide are mixed. The second layer ML may be a single layer formed of AlSiO₅. For example, the second layer ML may not include a plurality of layers.

The second layer ML may further include additional components in addition to the silicon dioxide (SiO₂) and the aluminum oxide (Al₂O₃). For example, in an embodiment the second layer ML may further include at least one of magnesium fluoride (MgF₂), calcium fluoride (CaF₂), aluminum fluoride (AlF₃), yttrium fluoride (YF₃), ytterbium fluoride (YbF₃), or magnesium oxide (MgO).

Like the first layer LRL, the second layer ML may be formed through an ion-assisted deposition process. However, embodiments of the present disclosure are not necessarily limited thereto, and the second layer ML may be formed through various deposition methods. For example, in an embodiment the second layer ML may be formed through an atomic layer deposition (ALD).

In an embodiment, the thickness d3 (e.g., length in the third direction DR3) of the second layer ML may be, for example, in a range of about 10 nm to about 20 nm. In a comparative embodiment in which the thickness d3 of the second layer ML is less than about 10 nm, the adhesion between the first layer LRL and the third layer FL may not be increased, and the mechanical strength of the window WM may be reduced. In a comparative embodiment in which the thickness d3 of the second layer ML is greater than about 20 nm, the reflectance of the window WM may increase, and the total thickness of the window WM may increase so that the total thickness of the display device may increase excessively.

In an embodiment, at a wavelength of about 550 nm, the refractive index of the second layer ML may be in a range of about 1.43 to about 1.50. As the refractive index of the second layer ML satisfies the above range at a wavelength of about 550 nm, the surface reflectance of the window WM may be reduced. The second layer ML may have a higher refractive index than the first layer LRL.

The third layer FL may be disposed on the second layer ML (e.g., in the third direction DR3), and may be a layer that increases anti-slip properties, scratch resistance, and the like of the surface of the window WM. In an embodiment, the third layer FL may be an anti-fingerprint layer that has high fingerprint resistance and prevents surface abrasion. In an embodiment, the third layer FL may be disposed directly on the second layer ML (e.g., in the third direction DR3). The third layer FL may be disposed on the uppermost layer of the window WM, and the upper surface of the third layer FL may define the uppermost surface of the window WM. For example, the upper surface of the third layer FL may define an outermost surface of the window WM.

The third layer FL may include a material having high scratch resistance and anti-slip properties and low refractive properties. In an embodiment, the third layer FL may include a fluorine-containing polymer. For example, the third layer FL may include, for example, a perfluoropolyether (PFPE) compound. In an embodiment, the third layer FL may include perfluoropolyether silane, perfluoroalkylether alkoxysilane, a perfluoroalkylether copolymer, or the like. Since the third layer FL includes the perfluoropolyether compound, the third layer FL may have increased fingerprint resistance and scratch resistance.

In an embodiment, the thickness d4 (e.g., length in the third direction DR3) of the third layer FL may be, for example, in a range of about 5 nm to about 40 nm. In a comparative embodiment in which the thickness d4 of the third layer FL is less than about 5 nm, the fingerprint resistance and scratch resistance of the window WM may be reduced. In a comparative embodiment in which the thickness d4 of the third layer FL is greater than about 40 nm, the reflectance of the window WM may be increased, and the total thickness of the window WM may be increased so that the total thickness of the display device may be increased excessively.

In an embodiment, at a wavelength of about 550 nm, the third layer FL may have a refractive index in a range of about 1.2 to about 1.5. In the window WM of an embodiment, at a wavelength of about 550 nm, the third layer FL may have a refractive index in a range of about 1.20 to about 1.35. As the refractive index of the third layer FL satisfies the above range at a wavelength of about 550 nm, the surface reflectance of the window WM may be reduced.

In an embodiment, the sum (d2+d3+d4) of the thicknesses of the first layer LRL, the second layer ML, and the third layer FL disposed on the base layer BL may be about 160 nm or less. In the window WM of an embodiment, the total thickness of the first layer LRL, the second layer ML, and the third layer FL disposed on the base layer BL of the window WM may be formed to be in a range of about 160 nm or less, so that the window WM having low reflection characteristics and high abrasion resistance, chemical resistance, polishing resistance characteristics, and hardness may be implemented.

In the window WM of an embodiment, the surface of the window WM may have a reflectance of about 6.0% or less at a wavelength of about 550 nm. In the window WM of an embodiment, the third layer FL may be disposed on the uppermost layer, and the upper surface of the third layer FL may have a reflectance of about 6.0% or less at a wavelength of about 550 nm. The upper surface of the third layer FL may have a reflectance in a range of about 5.8% to about 6.0% at a wavelength of about 550 nm. In the present specification, the “reflectance” of the window WM is defined as a ratio of light reflected to the outside among light incident in the inner direction of the window WM from the outside. The light reflected to the outside includes both the specular reflected light that is reflected at the same angle as the incident light, and the diffuse reflected light that is scattered and reflected in various directions. For example, in the present specification, the reflectance is defined as a specular component included (SCI) reflectance.

The window WM of an embodiment may have a reflection color value a* in a range of about −2 to about 2, and a reflection color value b* in a range of about-1.5 to about 0.5 at a wavelength of about 550 nm. In an embodiment in which each of the reflection color values a* and b* at a wavelength of about 550 nm satisfies the above-described range, the reflection of the external light on the surface of the window WM may be reduced, and thus the visibility of the display device DD may be increased. The window WM of an embodiment may exhibit a reflectance of about 6.0% or less by having reflection color values a* and b* in the above-described range. In the present specification, the reflection color values “a*” and “b*” of the window WM mean color values “a” and “b” in the CIE coordinate system, respectively. The color values a and b may be obtained from the CIE coordinate system in which an x-axis representing a value and a y-axis representing b value are perpendicular to each other. The color becomes red as the absolute value of the value increases in the positive direction. The color becomes green as the absolute value of the value increases in the negative direction. The color becomes yellow as the absolute value of the b value increases in the positive direction. The color becomes blue as the absolute value of the b value increases in the negative direction. In the present specification, the reflection color value of the window WM refers to a value measured in a specular component excluded (SCE) method.

Referring to FIGS. 1B, 3, and 4A together, when the anti-reflection layer 300 included in the display module DM includes the plurality of color filters 320 as in the display device DD of an embodiment, the display efficiency may be increased as compared to an embodiment which includes the polarizing layer having increased reflectance. In the display device DD according to an embodiment of the present disclosure, the window WM includes the first layer LRL, the second layer ML, and the third layer FL that include a material having a low refractive index, and thus the surface reflectance of the window WM may be reduced. Accordingly, the reflectance of the entire display device DD may be maintained relatively low.

In the window WM according to an embodiment of the present disclosure, each of the first layer LRL, the second layer ML, and the third layer FL includes a low refractive material, and the second layer ML includes silicon dioxide (SiO₂) and aluminum oxide (Al₂O₃). In addition, in the window WM according to an embodiment, as the weight ratio of the silicon dioxide (SiO₂) and the aluminum oxide (Al₂O₃) in the second layer ML is adjusted to be in a range of about 25:75 to about 35:65, the adhesion between layers may be increased and the optical characteristics, abrasion resistance, and scratch resistance of the window WM may be increased. The window WM according to an embodiment includes a structure of the first layer LRL and the second layer ML provided as a single layer while securing low refractive properties, and the content of the silicon dioxide (SiO₂) and the aluminum oxide (Al₂O₃) included in the second layer ML is adjusted to a specific range, thereby exhibiting high optical characteristics and increasing the abrasion resistance and scratch resistance. Accordingly, the reliability and durability of the display device DD including the window WM may be increased.

The window WM according to an embodiment of the present disclosure may include the second layer ML interposed between the first layer LRL and the third layer FL (e.g., in the third direction DR3), and the content of the silicon dioxide (SiO₂) and the aluminum oxide (Al₂O₃) included in the second layer ML is adjusted to a specific range so that the chemical resistance and polishing resistance of the window WM may be increased. In the window WM of an embodiment, the weight ratio of the silicon dioxide (SiO₂) and the aluminum oxide (Al₂O₃) included in the second layer ML is adjusted to be in a range of about 25:75 to about 35:65 so that the chemical resistance and polishing resistance of the window WM may be increased, and accordingly, the durability and reliability of the display device DD including the window WM may be increased.

In a comparative embodiment in which the weight ratio of the silicon dioxide (SiO₂) and the aluminum oxide (Al₂O₃) included in the second layer ML does not satisfy the above-described range, the second layer ML or the third layer FL may be worn and lost in the evaluation of the chemical resistance in which the friction is applied under a condition in which a solvent, such as alcohol, is applied, or the evaluation of the abrasion resistance in which the friction is applied with steel-wool or the like. In the window WM of an embodiment of the present disclosure, the content of the silicon dioxide (SiO₂) and the aluminum oxide (Al₂O₃) included in the second layer ML is adjusted to a specific range so that when the friction is applied under the condition in which a solvent, such as alcohol is applied, the second layer ML or the third layer FL may be prevented from being lost, and when the friction is applied with steel-wool or the like, the second layer ML or the third layer FL may be prevented from being lost. Accordingly, the chemical resistance and polishing resistance of the window WM may be increased, and thus, the durability and the reliability of the display device DD including the window WM may be increased.

The window WM according to an embodiment of the present disclosure may include the second layer ML interposed between the first layer LRL and the third layer FL (e.g., in the third direction DR3), and the scratch resistance of the window WM may be increased by adjusting the content of the silicon dioxide (SiO₂) and the aluminum oxide (Al₂O₃) included in the second layer ML to a specific range. In a comparative embodiment in which the weight ratio of the silicon dioxide (SiO₂) and the aluminum oxide (Al₂O₃) included in the second layer ML does not satisfy the above-described range, the second layer ML may not prevent the friction load in the evaluation of the scratch resistance in which the vibration friction is applied with ceramic particles or the like, and thus the first layer LRL disposed below may be scratched. In the window WM of an embodiment of the present disclosure, the content of the silicon dioxide (SiO₂) and the aluminum oxide (Al₂O₃) included in the second layer ML is adjusted to a specific range so that the second layer ML may be prevented from being worn or lost even when the friction with the ceramic particles is applied under a certain range of vibration conditions. Accordingly, the scratch resistance of the window WM may be increased.

The surface reflectance, sense of reflection color, chemical resistance, polishing resistance, and vibration friction evaluation of the windows of Examples and Comparative Examples are shown in Table 1 below. In Table 1, the windows of Examples and Comparative Examples are windows having a structure in which the first to third layers are sequentially stacked on the base layer as shown in FIG. 4A. The windows of Examples and Comparative Examples are produced by changing a mixing ratio of the silicon dioxide (SiO₂) and the aluminum oxide (Al₂O₃) in the second layer. The windows of Examples are windows in which the weight ratio of the silicon dioxide (SiO₂) and the aluminum oxide (Al₂O₃) in the second layer satisfies the range of about 25:75 to about 35:65, and the windows of Comparative Examples are windows in which the weight ratio of the silicon dioxide (SiO₂) and the aluminum oxide (Al₂O₃) in the second layer deviates from the range of about 25:75 to about 35:65.

In the windows of Examples and Comparative Examples, the base layer was formed of a glass substrate, the first layer was formed of magnesium fluoride (MgF₂) to have a thickness of about 70 nm, the second layer was formed of a solid solution in which the silicon dioxide (SiO₂) and the aluminum oxide (Al₂O₃) are mixed in the content ratio shown in Table 1 below to have a thickness of about 15 nm, and the third layer was formed of perfluoropolyether (PFPE) to have a thickness of about 36 nm.

In Table 1, the reflectance was measured at a wavelength of about 550 nm in a specular component included (SCI) mode using equipment of CM-3700A (KONICA MINOLTA, Inc.). For the sense of reflection color, respective color shift values of color coordinates a* and b* at a wavelength of about 550 nm based on specular component excluded (SCE) reflection were measured using equipment of CM-3700A (KONICA MINOLTA, Inc.), and the results are shown in Table 1. When the color coordinate value a* is about −2 to about 2 and the color coordinate value b* is about −1.5 to about 0.5, the effect of embodiments of the present disclosure may be achieved. When the ranges of the reflection color values a* and b* of the window satisfy the above-described ranges, the screen quality may be high when the window is applied to the display device. The chemical resistance evaluation was performed by rubbing the window 3,000 times with a load of 1 Kgf with an industrial eraser under the condition in which alcohol (ethanol, purity 99.99%) is applied, and measuring the contact angle of the surface of the window, and the results are shown in Table 1. The polishing resistance evaluated was performed by rubbing the window 2,500 or 3,000 times with a load of 1 Kgf with steel-wool and then measuring the contact angle of the window surface, and the results are shown in Table 1. Both the chemical resistance evaluation and the polishing resistance evaluation were performed by measuring the contact angle of deionized water with respect to the surface of the sample window. For the vibration friction evaluation, a sample in a container containing a surfactant solution and ceramic particles was put therein, and the sample was subjected to friction by applying vibration of 50 Hz, and then the surface of the sample was observed with the naked eyes to evaluate the occurrence of scratches, and the results are shown in Table 1. With the sample being observed with the naked eyes after the vibration friction experiment, it was evaluated as “NG” when scratches occurred, and “OK” when no scratches occurred. In the abrasion resistance evaluation, the contact angle may mean an angle formed by the surface of the window, to which moisture is attached, and the surface of water. As the contact angle increases, the characteristic in that the moisture attached to the surface of the window is easily wiped may be exhibited.

TABLE 1

| | | | | | Abrasion resistance | | |
|---|---|---|---|---|---|---|---|
| | | | | | (contact angle) | | |
| | | | | | Chemical | | Vibration |
| | | Surface | Sense of reflection color | | resistance | Steel-wool | friction |
| | SiO₂:Al₂O₃ | reflectance | (SCE) | | after 3K | after 3K | 50 Hz, |
| Division | (weight %) | (SCI) | a* | b* | (°) | (°) | 30 min. |
| Example 1 | 25:75 | 6.0% | +1.25 | −0.97 | 107° | 109° | OK |
| Example 2 | 30:70 | 5.9% | +0.87 | −0.25 | 107° | 106° | OK |
| Example 3 | 35:65 | 5.85% | +0.48 | −0.12 | 104° | 106° | OK |
| Comparative | 20:80 | 6.2% | +2.15 | −1.67 | 108° | 109° | OK |
| Example 1 | | | | | | | |
| Comparative | 40:60 | 5.8% | +0.27 | −0.06 | 107° | 105° | NG |
| Example 2 | | | | | | | |
| Comparative | 70:30 | 5.65% | +0.07 | −0.02 | 103° | 101° | NG |
| Example 3 | | | | | | | |

Referring to the results of Table 1, it may be confirmed that the windows of Examples 1-3 exhibit a low surface reflectance of 6.0% or less compared to the windows of Comparative Examples 1-3, and at the same time exhibit high abrasion resistance and high scratch resistance.

Referring to Examples and Comparative Examples, it may be confirmed that the reflectance is increased in proportion to the content of the aluminum oxide (Al₂O₃) based on the total weight of the silicon dioxide (SiO₂) and the aluminum oxide (Al₂O₃) included in the second layer. In addition, it may be confirmed that as the content of the aluminum oxide (Al₂O₃) in the second layer decreases, the abrasion resistance and scratch resistance characteristics decrease. For example, it may be observed that the addition of the aluminum oxide (Al₂O₃) affects the overall reflectance and mechanical properties of the window.

When comparing Examples 1 to 3 with Comparative Example 1, it may be confirmed that the window of Comparative Example 1 exhibits a contact angle characteristic similar to those of Examples after the evaluation of chemical resistance and polishing resistance, but the surface reflectance of Comparative Example 1 is increased by about 0.2% or more compared to Examples 1-3. In addition, it may be confirmed that the window of Comparative Example 1 has a reflection color value a* that deviates from the range of about-2 to about 2, and a reflection color value b* that deviates from the range of about-1.5 to about 0.5, as compared with Examples.

The window of Comparative Example 1 corresponds to a case in which the content of the aluminum oxide (Al₂O₃) in the second layer is higher than that of the windows of Examples 1 to 3. When comparing Examples 1 to 3 with Comparative Example 1, it may be seen that when the content of the aluminum oxide (Al₂O₃) is increased relative to the silicon dioxide (SiO₂) included in the second layer, the mechanical properties of the window are increased, but when the content exceeds a predetermined range, the reflectance characteristic is reduced. As in Comparative Example 1, it may be seen that when the content of the aluminum oxide (Al₂O₃) is greater than about 75 wt % based on the total weight of the silicon dioxide (SiO₂) and the aluminum oxide (Al₂O₃), the surface reflectance exceeds about 6.0%. On the other hand, it may be confirmed that the window of Example in which the content of the aluminum oxide (Al₂O₃) is about 75 wt % or less exhibits a reflectance of about 6.0% or less, but exhibits a contact angle similar to that of Comparative Example 1 even after the evaluation of chemical resistance and abrasion resistance, and exhibits high mechanical durability because no scratches are found even after the vibration friction evaluation.

When comparing Examples 1 to 3 with Comparative Examples 2 and 3, it may be confirmed that the windows of Comparative Examples 2 and 3 exhibit a low reflectance of about 6.0% or less, but the abrasion resistance and scratch resistance are reduced compared to Examples 1-3. It may be seen that the lower the content of the aluminum oxide (Al₂O₃) based on the total weight of the silicon dioxide (SiO₂) and the aluminum oxide (Al₂O₃) included in the second layer, the better the reflectance characteristic. However, the abrasion resistance and scratch resistance are reduced when the content is less than a predetermined range. As in Comparative Examples 2 and 3, when the content of the aluminum oxide (Al₂O₃) is less than about 65 wt % based on the total weight of the silicon dioxide (SiO₂) and the aluminum oxide (Al₂O₃), it may be confirmed that the contact angle is decreased in the evaluation of chemical resistance or abrasive resistance as compared to Examples 1-3, and the surface scratch is generated after the vibration friction evaluation is performed. On the other hand, it may be confirmed that the abrasion resistance and scratch resistance of Examples 1 to 3 in which the content of the aluminum oxide (Al₂O₃) is about 65 wt % or more are increased compared to Comparative Examples.

Accordingly, it may be confirmed that the window of an embodiment of the present disclosure has high anti-reflection characteristics, abrasion resistance, and scratch resistance when the weight ratio of the silicon dioxide (SiO₂) and the aluminum oxide (Al₂O₃) included in the second layer satisfies the range of about 25:75 to about 35:65. The window of the display device may exhibit high mechanical properties capable of protecting the display device from external stimuli while requiring a low reflection characteristic capable of reducing reflection of light incident from the outside of the display device. In particular, since the window disposed on the upper portion of the display device may receive an external artificial contact, the possibility of scratches or abrasion is high, and thus high resistance to vibration abrasion or the like may be required. However, it is very difficult to simultaneously satisfy the mechanical and optical properties required for the window of the display device. The window WM according to an embodiment of the present disclosure includes the first layer LRL, the second layer ML, and the third layer FL, and may maintain high optical characteristics and exhibit high mechanical properties by adjusting the content of the silicon dioxide (SiO₂) and the aluminum oxide (Al₂O₃) included in the second layer ML to a specific range. Accordingly, when the window WM of an embodiment is applied to the display device, the reliability and durability of the display device may be increased.

Referring to FIG. 4B, a window WM-1 of an embodiment may further include a fourth layer SML disposed between a base layer BL and a first layer LRL (e.g., in the third direction DR3).

The fourth layer SML may be disposed on the base layer BL, and may be a layer for increasing adhesion between the base layer BL and the first layer LRL. The fourth layer SML may be an adhesion promoter having high adhesion with respect to each of the base layer BL and the first layer LRL and increasing interlayer adhesion between the base layer BL and the first layer LRL. The fourth layer SML may be disposed directly on the base layer BL. The fourth layer SML may be in direct contact with the base layer BL and the first layer LRL.

The fourth layer SML may have low refractive properties and high mechanical strength, and include a material for increasing adhesion. In an embodiment, the fourth layer SML may include magnesium oxide (MgO). In an embodiment, the fourth layer SML may further include silicon dioxide (SiO₂) in addition to magnesium oxide. The fourth layer SML may include a solid solution containing magnesium oxide in the structure. The fourth layer SML may include, for example, a solid solution in which the magnesium oxide and the silicon dioxide are mixed. The fourth layer SML includes a solid solution containing magnesium oxide, and thus the adhesion to the first layer LRL including magnesium oxide as the fourth layer SML may be increased. Like the first layer LRL, the fourth layer SML may be formed through the ion-assisted deposition process.

In an embodiment, the thickness of the fourth layer SML may be, for example, in a range of about 5 nm to about 25 nm. In a comparative embodiment in which the thickness of the fourth layer SML is less than about 5 nm, the effect of increasing the adhesion between the base layer BL and the first layer LRL may not be achieved. In a comparative embodiment in which the thickness of the fourth layer SML is greater than about 25 nm, the reflectance of the window WM-1 may increase, and the total thickness of the window WM-1 may increase so that the total thickness of the display device may be increased excessively.

In an embodiment, at a wavelength of about 550 nm, the fourth layer SML may have a refractive index in a range of about 1.3 to about 1.6. In the window WM-1 of an embodiment, at a wavelength of about 550 nm, the fourth layer SML may have a refractive index in a range of about 1.45 to about 1.50. As the refractive index of the fourth layer SML satisfies the above range at a wavelength of about 550 nm, the surface reflectance of the window WM-1 may be reduced.

Referring to FIG. 4C, the window WM-2 of an embodiment may further include a fifth layer HRL disposed between the base layer BL and the first layer LRL (e.g., in the third direction DR3). The fifth layer HRL may be a layer having a higher refractive index than other layers. In the window WM-2 of an embodiment, at a wavelength of about 550 nm, the fifth layer HRL may have a refractive index in a range of about 1.7 to about 3.0. At a wavelength of about 550 nm, the fifth layer HRL may have a refractive index in a range of about 2.0 to about 2.5. At a wavelength of about 550 nm, the fifth layer HRL may have a refractive index in a range of about 2.33.

The fifth layer HRL may be disposed on the base layer BL and have high refractive properties, and thus may further reduce the surface reflectance of the window WM-2. The window WM-2 of an embodiment may have a structure in which the first layer LRL, the second layer ML, and the third layer FL having low refractive properties are sequentially stacked on the fifth layer HRL (e.g., in the third direction DR3) having high refractive properties, so that the surface reflectance of the window WM-2 may be reduced, and the fifth layer HRL may have high adhesion with respect to each of the base layer BL and the first layer LRL so that the interlayer adhesion between the base layer BL and the first layer LRL may be maintained high. In an embodiment, the fifth layer HRL may be disposed directly on the base layer BL (e.g., in the third direction DR3). The fifth layer HRL may be in direct contact with the base layer BL and the first layer LRL.

The fifth layer HRL may have high refractive properties and high mechanical strength, and include a material for increasing adhesion. In an embodiment, the fifth layer may include at least one of zinc oxide (ZnO₂), hafnium oxide (HfO₂), tantalum oxide (Ta₂O₅), niobium oxide (Nb₂O₅), titanium oxide (TiO₂), ytterbium oxide (Y₂O₃), silicon nitride (Si₃N₄), strontium titanate (SrTiO₃), tungsten oxide (WO₃), or aluminum nitride (AlN). For example, the fifth layer HRL may include niobium oxide (Nb₂O₅). Since the fifth layer HRL includes niobium oxide (Nb₂O₅), the fifth layer HRL may have a high refractive index in the above-described range, and may have high adhesion to each of the base layer BL and the first layer LRL which are in direct contact with the fifth layer HRL. Like the first layer LRL, the fifth layer HRL may be formed through the ion-assisted deposition process. In the process of forming the fifth layer HRL, high refractive materials such as zinc oxide (ZnO₂), hafnium oxide (HfO₂), tantalum oxide (Ta₂O₅), niobium oxide (Nb₂O₅), titanium oxide (TiO₂), ytterbium oxide (Y₂O₃), silicon nitride (Si₃N₄), strontium titanate (SrTiO₃), tungsten oxide (WO₃), and aluminum nitride (AlN) are deposited on the surface of the base layer BL in the form of a particle, and an ionized oxygen (O₂) gas is provided together during the deposition process, thereby increasing adhesion of the deposition film to the surface of the base layer BL.

In an embodiment, the thickness d5 (e.g., length in the third direction DR3) of the fifth layer HRL may be, for example, about 5 nm to about 25 nm. For example, the thickness d5 of the fifth layer HRL may be about 10 nm. In a comparative embodiment in which the thickness d5 of the fifth layer HRL is less than about 5 nm, the reflectance of the window WM-2 may be increased, and the adhesion between the base layer BL and the first layer LRL may not be increased. In a comparative embodiment in which the thickness d5 of the fifth layer HRL is greater than about 25 nm, the total thickness of the window WM-2 may be increased so that the total thickness of the display device may be increased excessively.

In the window WM-2 of an embodiment, the surface of the window WM-2 may have a reflectance of about 6.0% or less at a wavelength of about 550 nm. In the window WM-2 of an embodiment, the third layer FL may be disposed on the uppermost layer, and the upper surface of the third layer FL may have a reflectance of about 6.0% or less at a wavelength of about 550 nm. The upper surface of the third layer FL may have a reflectance in a range of about 5.8% to about 6.0% at a wavelength of about 550 nm. The window WM-2 according to an embodiment of the present disclosure further includes the fifth layer HRL provided between the first layer LRL and the base layer BL (e.g., in the third direction DR3), and thus may have a lower surface reflectance than an embodiment in which the first layer LRL is disposed directly on the base layer BL without the fifth layer HRL. For example, in the window WM-2 according to an embodiment, the fifth layer HRL having the high refractive properties may be provided between the base layer BL and the first layer LRL (e.g., in the third direction DR3), and thus, the high refractive layer and the low refractive layer may be sequentially disposed on the base layer, thereby implementing a structure that further reduces the surface reflectance of the window WM-2. in an embodiment, since a material such as niobium oxide (Nb₂O₅) is deposited on the upper surface of the base layer BL through the ion-assisted deposition process, the fifth layer HRL included in the window WM-2 may have high adhesion to the base layer BL, and thus may have abrasion resistance, chemical resistance, and polishing resistance equal to those of the window in which the fifth layer HRL is omitted. Accordingly, the display device including the window WM-2 may have low reflection characteristics while the durability thereof is maintained.

Referring to FIG. 4D, the window WM-3 of an embodiment may further include a sixth layer CLRL disposed below the base layer BL. The sixth layer CLRL may be a layer having a low refractive index. In the window WM-3 of an embodiment, at a wavelength of about 550 nm, the sixth layer CLRL may have a refractive index in a range of about 1.3 to about 1.5. In an embodiment, at a wavelength of about 550 nm, the sixth layer CLRL may have a refractive index in a range of about 1.38 to about 1.40.

The sixth layer CLRL may be disposed below the base layer BL and have low refractive properties, and thus may further reduce the surface reflectance of the window WM-3. In addition, the window WM-3 of an embodiment further includes the sixth layer CLRL disposed below the base layer BL, and thus may have increased sense of reflection color as compared to the window that does not include the sixth layer CLRL. In an embodiment, the sixth layer CLRL may be disposed below the base layer BL and may be spaced apart from the first layer LRL with the base layer BL interposed therebetween (e.g., in the third direction DR3). For example, when the window WM-3 of an embodiment is applied to the display device DD (see FIG. 2), the sixth layer CLRL may be disposed adjacent to the display module DM (see FIG. 2) compared to the base layer BL, the first layer LRL, the second layer ML, and the third layer FL. In an embodiment, the sixth layer CLRL may be disposed directly below the base layer BL. The sixth layer CLRL may be in direct contact with the lower surface of the base layer BL.

In an embodiment, the sixth layer CLRL may include a material having a low refractive index and high adhesion to the base layer BL. The sixth layer CLRL may include a first material similar to the first layer LRL, and the first material may include a material having a lower refractive index than the refractive index of the material included in the base layer BL as described above. In an embodiment, the first material included in the sixth layer CLRL may include, for example, at least one of silicon dioxide, molten silicon dioxide, fluorine-doped molten silicon dioxide, magnesium fluoride (MgF₂), calcium fluoride (CaF₂), aluminum fluoride (AlF₃), yttrium fluoride (YF₃), ytterbium fluoride (YbF₃), aluminum oxide (Al₂O₃), or magnesium oxide (MgO). For example, the sixth layer CLRL may include at least one of magnesium fluoride (MgF₂) or magnesium oxide (MgO) as the first material.

In an embodiment, the sixth layer CLRL may include magnesium oxide (MgO). The sixth layer CLRL may further include magnesium fluoride (MgF₂) and yttrium oxyfluoride (YOF) in addition to, or instead of, magnesium oxide. The sixth layer CLRL may include a solid solution containing magnesium oxide in the structure. In an embodiment, the sixth layer CLRL may include, for example, a solid solution in which the magnesium oxide, the magnesium fluoride, and the yttrium oxyfluoride are mixed. Alternatively, the sixth layer CLRL may include magnesium fluoride (MgF₂). The sixth layer CLRL may be a single layer formed of magnesium fluoride (MgF₂).

In an embodiment, the sixth layer CLRL may include the same material as the first layer LRL or a different material from the first layer LRL. For example, in an embodiment each of the first layer LRL and the sixth layer CLRL may include magnesium fluoride. Each of the first layer LRL and the sixth layer CLRL may include a solid solution in which the magnesium oxide, the magnesium fluoride, and the yttrium oxyfluoride are mixed. Alternatively, in an embodiment one among the first layer LRL and the sixth layer CLRL may include magnesium fluoride, and the other may include a solid solution in which the magnesium oxide, the magnesium fluoride, and the yttrium oxyfluoride are mixed.

Like the first layer LRL, the sixth layer CLRL may be formed through the ion-assisted deposition process. In the process of forming the sixth layer CLRL, at least one among materials such as magnesium oxide, magnesium fluoride, and yttrium oxyfluoride is deposited on the surface of the base layer BL in the form of a particle, and an ionized argon (Ar) gas or oxygen (O₂) gas is provided together during the deposition process so that the adhesion of the deposition film to the surface of the base layer BL may be increased.

In an embodiment, the thickness d6 (e.g., length in the third direction DR3) of the sixth layer CLRL may be, for example, in a range of about 50 nm to about 130 nm. In a comparative embodiment in which the thickness d6 of the sixth layer CLRL is less than about 50 nm, the surface reflectance of the window WM-3 may not be sufficiently reduced. In a comparative embodiment in which the thickness d6 of the sixth layer CLRL is greater than about 130 nm, the mechanical strength of the window WM-3 may be reduced so that the durability may be reduced, and the total thickness of the window WM-3 may be increased so that the total thickness of the display device may be increased excessively.

In the window WM-3 according to an embodiment of the present disclosure, the surface of the window WM-3 may have a reflectance of about 6.0% or less at a wavelength of about 550 nm. In the window WM-3 of an embodiment, the third layer FL may be disposed on the uppermost layer, and the upper surface of the third layer FL may have a reflectance of about 6.0% or less at a wavelength of about 550 nm. The upper surface of the third layer FL may have a reflectance in a range of about 5.8% to about 6.0% at a wavelength of about 550 nm. The window Wm-e according to an embodiment of the present disclosure further includes the sixth layer CLRL provided below the base layer BL, and thus the window Wm-e may have a lower surface reflectance than when there is not a separate layer disposed below the base layer BL. For example, the window WM-3 according to an embodiment may have a structure in which the first layer LRL and the sixth layer CLRL having low refractive properties are respectively provided on both sides of the base layer BL, thereby implementing a structure that further reduces the surface reflectance of the window WM-3. Accordingly, the display device including the window WM-3 may have increased low reflection characteristics.

According to an embodiment of the present disclosure, the window includes a plurality of layers which are disposed on the base layer and includes a specific material, and thus may have low refractive properties and high adhesion between layers, and also have increased mechanical strength, such as abrasion resistance, chemical resistance, and polishing resistance characteristics. Accordingly, the durability and reliability of the display device including the window may be increased.

Although the present disclosure has been described with reference to non-limiting embodiments, it will be understood that embodiments of the present disclosure should not necessarily be limited to these embodiments but various changes and modifications can be made by those skilled in the art without departing from the spirit and scope of the present disclosure. Accordingly, the technical scope of the present disclosure is not intended to be limited to the described embodiments set forth in the detailed description of the specification.

What is claimed is:

1. A window comprising:
a base layer;
a first layer disposed on the base layer;
a second layer disposed on the first layer; and
a third layer disposed on the second layer,
wherein the second layer comprises silicon dioxide (SiO₂) and aluminum oxide (Al₂O₃), and
a weight ratio of the silicon dioxide to the aluminum oxide in the second layer is in a range of about 25:75 to about 35:65.

2. The window of claim 1, wherein:
the second layer is disposed directly on the first layer; and
the third layer is disposed directly on the second layer.

3. The window of claim 1, wherein the second layer has a thickness in a range of about 10 nm to about 20 nm.

4. The window of claim 1, wherein, at a wavelength of about 550 nm, the second layer has a refractive index in a range of about 1.43 to about 1.50.

5. The window of claim 1, wherein:
at a wavelength of about 550 nm, the first layer has a refractive index in a range of about 1.3 to about 1.5; and
at a wavelength of about 550 nm, the third layer has a refractive index in a range of about 1.2 to about 1.5.

6. The window of claim 1, wherein:
a refractive index of the first layer is less than a refractive index of the base layer; and
a refractive index of the second layer is greater than the refractive index of the first layer.

7. The window of claim 1, wherein the second layer comprises a solid solution in which the silicon dioxide and the aluminum oxide are mixed.

8. The window of claim 1, wherein, at a wavelength of about 550 nm, a reflectance on an upper surface of the third layer is about 6.0% or less.

9. The window of claim 1, wherein the third layer comprises a fluorine-containing polymer.

10. The window of claim 1, wherein the base layer comprises a glass substrate or a polymer film.

11. The window of claim 1, wherein:
the first layer has a thickness in a range of about 60 nm to about 80 nm; and
the third layer has a thickness in a range of about 5 nm to about 40 nm.

12. The window of claim 1, further comprising a fourth layer disposed between the base layer and the first layer, wherein the fourth layer comprises magnesium oxide.

13. The window of claim 1, further comprising a fifth layer disposed between the base layer and the first layer, the fifth layer has a refractive index of about 1.7 to about 3.0 at a wavelength of about 550 nm.

14. The window of claim 13, wherein the fifth layer comprises at least one compound selected from the group consisting of zinc oxide (ZrO₂), hafnium oxide (HfO₂), tantalum oxide (Ta₂O₅), niobium oxide (Nb₂O₅), titanium oxide (TiO₂), ytterbium oxide (Y₂O₃), silicon nitride (Si₃N₄), strontium titanate (SrTiO₃), tungsten oxide (WO₃), and aluminum nitride (AlN).

15. The window of claim 1, further comprising a sixth layer disposed below the base layer, the sixth layer has a refractive index in a range of about 1.3 to about 1.5 at a wavelength of about 550 nm.

16. The window of claim 15, wherein the sixth layer comprises at least one compound selected from the group consisting of magnesium oxide, magnesium fluoride, or yttrium oxyfluoride.

17. A display device comprising:
a display module; and
a window disposed on the display module,
wherein the window comprises:
a base layer;
a first layer disposed on the base layer;
a second layer disposed on the first layer; and
a third layer disposed on the second layer,
wherein the second layer comprises silicon dioxide (SiO₂) and aluminum oxide (Al₂O₃), and
a weight ratio of the silicon dioxide to the aluminum oxide in the second layer is in a range of about 25:75 to about 35:65.

18. The display device of claim 17, wherein the display module comprises:
a base substrate;
a circuit layer disposed on the base substrate;
a light emitting element layer disposed on the circuit layer, the light emitting element layer including a plurality of light emitting elements;
an encapsulation layer disposed on the light emitting element layer; and
an anti-reflection layer disposed on the encapsulation layer,
wherein the anti-reflection layer comprises a division layer having a plurality of division openings respectively overlapping the plurality of light emitting elements, and a plurality of color filters respectively disposed to correspond to the plurality of division openings.

19. The display device of claim 17, wherein the first layer is spaced apart from the display module with the base layer interposed therebetween.

20. The display device of claim 17, wherein an upper surface of the third layer defines an outermost surface of the window.
